(19) United States
(12) Patent Application Publication
(10) Pub. No.: US 2013/0269995 A1
(43) Pub. Date: Oct. 17, 2013

(54) PRINTED CIRCUIT BOARD

(71) Applicants: HONG FU JIN PRECISION INDUSTRY (ShenZhen) CO., LTD., (US); HON HAI PRECISION INDUSTRY CO., LTD., New Taipei (TW)

(72) Inventors: Lu-Qing MENG, Shenzhen (CN); Hsing-Suang KAO, New Taipei (TW)

(73) Assignees: HON HAI PRECISION INDUSTRY CO., LTD., New Taipei (TW); HONG FU JIN PRECISION INDUSTRY (ShenZhen) CO., LTD, Shenzhen (CN)

(21) Appl. No.: 13/851,946

(22) Filed: Mar. 27, 2013

(30) Foreign Application Priority Data
Apr. 11, 2012 (CN) 201210103991.7

(51) Int. Cl. H05K 1/02

(52) U.S. Cl. CPC H05K 1/0296
USPC 174/262

(57) ABSTRACT

A printed circuit board is provided. The printed circuit board includes a number of welding points in a row for soldering of a series of welding feet of a component thereto. Each welding point includes a welding hole defined in the printed circuit board and a C-shaped welding pad surrounding the welding hole. The welding pads have an opening facing an adjacent welding pad.

### BACKGROUND

1. Technical Field

The present disclosure relates to a printed circuit board which can effectively overcome solder bridging problems.

2. Description of Related Art

In general, product specification requires that a pitch between two adjacent welding feet of an electronic component, such as a connector, is not greater than 2.5 millimeter (mm) However, wave soldering process requires that a gap between two adjacent welding points is greater than 0.7 mm, otherwise, it is easy to cause solder bridging problems.

For example, as shown in FIG. 1, a series of welding points 11 are designed on a printed circuit board 100. Each welding point 11 includes a welding hole 111, which is configured for insertion of one of a series of welding feet of a component, such as a connector, to mount the connector on the printed circuit board 100. As shown in FIG. 2, the pitch between two adjacent welding feet 12 and 12′ is 2.5 mm, the radius of each of the welding holes 111 is 0.4 mm, and the width of the copper ring 112 surrounding the welding hole 111 is 0.5 mm. Therefore, the gap between two adjacent welding points is calculated as follows: 2.5−0.4*2−0.5*2=0.7 mm. Thereby, as shown in FIG. 3, in the wave soldering process, solder bridging problems will be caused, which will further cause short circuit problem.

Therefore, what is needed is a printed circuit board to overcome the problems mentioned above.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is a schematic diagram of a printed circuit board of related art, showing a series of welding points designed on the printed circuit board.

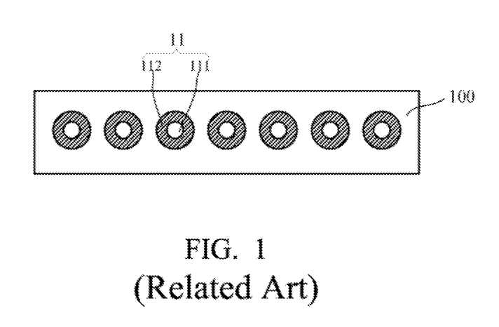

FIG. 2 is a schematic diagram showing two welding feet of a component respectively received by corresponding welding holes of the welding points of FIG. 1.

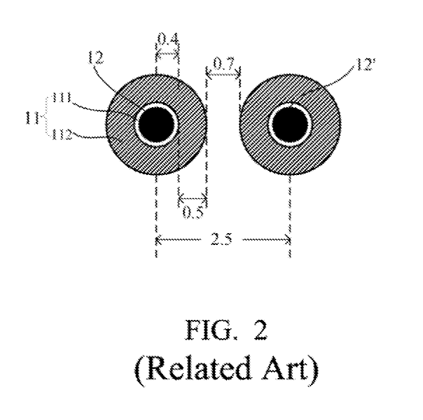

FIG. 3 is a schematic diagram of the printed circuit board of FIG. 1, showing the series of welding points after being soldered.

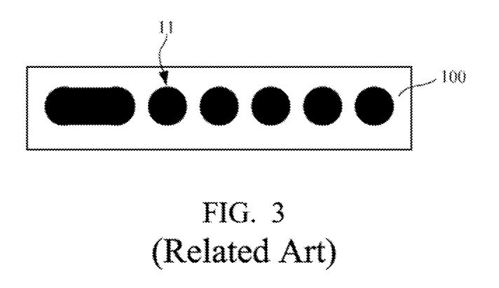

FIG. 4 is a schematic diagram of a novel printed circuit board, showing a series of welding points designed on the novel printed circuit board, according to an embodiment.

FIG. 5 is a schematic diagram of the novel printed circuit board of FIG. 4, showing the series of welding points after being soldered.

### DETAILED DESCRIPTION

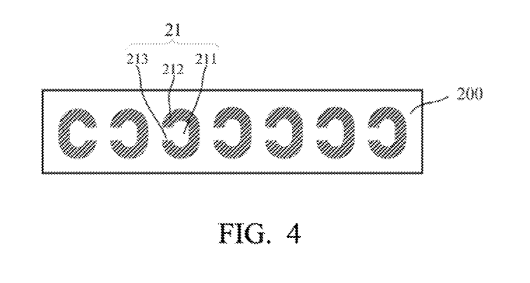

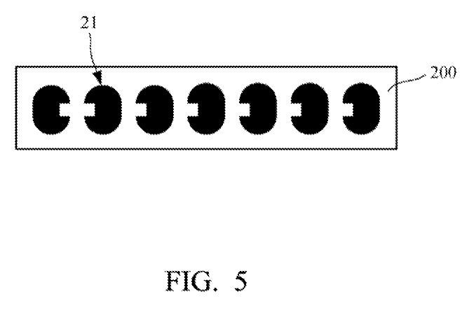

Referring to FIGS. 4 and 5, a printed circuit board (PCB) 200 includes a series of welding points 21 in a row for soldering of a series of welding feet of a component (not shown), such as a connector, to mount the component on the PCB 200. Each welding point 21 includes a welding hole 211 defined in the PCB 200 and a C-shaped welding pad 212 surrounding the welding hole 211. In the embodiment, both of the welding hole 211 and the welding pad 212 have a substantially elliptical contour, and the welding pad 212 has an opening 213 facing one of its adjacent welding pads.

In soldering, the C-shaped of the welding pads 212 makes solder evenly adhere to the welding pads 212. Further, the welding pads 212 are designed in a “C” shape, and the opening 213 of the “C” shape increases the space between the solder adhering to two adjacent welding points, thus reducing the chances of bridging between adjacent welding points. With such structures, solder bridging problems can be thus avoided, without increasing the space between two adjacent welding feet of the connector, or increasing the gap between two adjacent welding points.

Moreover, it is to be understood that the disclosure may be embodied in other forms without departing from the spirit thereof. Thus, the present examples and embodiments are to be considered in all respects as illustrative and not restrictive, and the disclosure is not to be limited to the details given herein.

What is claimed is:

1. A printed circuit board comprising a plurality of welding points in a row for soldering of a series of welding feet of a component thereto, each welding point comprising:
a welding hole defined in the printed circuit board; and
a C-shaped welding pad surrounding the welding hole, the welding pad having an opening facing an adjacent welding pad.

2. The printed circuit board as described in claim 1, wherein both of the welding hole and the welding pad have a substantially elliptical contour.
